(19) United States
(12) Patent Application Publication
(10) Pub. No.: US 2008/0128118 A1
(43) Pub. Date: Jun. 5, 2008

(54) HEAT DISSIPATION DEVICE WITH A HEAT PIPE

(75) Inventors: YONG-DONG CHEN, Shenzhen (CN); GUANG YU, Shenzhen (CN); CHUN-CHI CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/566,011

(22) Filed: Dec. 1, 2006

(51) Int. Cl. H05K 7/20

(52) U.S. Cl. 165/104.33; 165/80.3; 361/700

(57) ABSTRACT

A heat dissipation device includes a base (40) and fins (30) attached to the base (40) and two heat pipes (20). The fins (30) include a first portion (325) and a second portion (326) connecting with one side of the first portion (325), and the second portion (326) is higher than the first portion (325). Each of the heat pipes (20) includes an evaporating portion (22) sandwiched between the base (40) and the first portion (325) of the fins (30), a condensing portion (24) inserted into the second portion (326) of the fins (30).

### BACKGROUND OF THE INVENTION

1. Field of the Invention

The present invention generally relates to heat dissipation devices, and more particularly to a heat dissipation device having a heat pipe for cooling an electronic component, such as an integrated circuit package.

2. Description of Related Art

Electronic components, such as central processing units (CPUs) comprise numerous circuits operating at high speed and generating substantial heat. Under most circumstances, it is necessary to cool the CPUs in order to maintain safe operating conditions and assure that the CPUs function properly and reliably. In the past, various approaches have been used to cool electronic components. Typically, a finned metal heat sink is attached to an outer surface of the CPU to remove the heat therefrom. The heat absorbed by the heat sink is then dissipated to ambient air. The related finned metal heat sink is made of highly heat-conductive metal, such as copper or aluminum, and generally comprises a base for contacting the CPU to absorb the heat therefrom and a plurality of fins formed on the base for dissipating the heat. However, as the operating speed of electronic components has increased markedly in recent years, such a related heat sink, which transfers the heat only by metal conduction, is not competent for dissipating so much heat any more. The heat of the bottom of the metal heat sink can not be transferred to the whole heat dissipation device quickly, and especially can not be transferred to the fins far away from the bottom of the metal heat sink.

Heat pipes, which operate by phase change of working liquid sealed in a hollow pipe, have been widely used due to their excellent heat transfer properties. Accordingly, heat dissipation devices equipped with heat pipes are devised in various manners and widely used. How to enable the heat dissipation device equipped with heat pipes to have an optimal performance becomes a goal that persons skilled in the art endeavor to achieve.

Accordingly, what is needed is a heat dissipation device with heat pipes which has an enhanced heat dissipation performance.

### SUMMARY OF THE INVENTION

According to an embodiment of the present invention, a heat dissipation device comprises a base, a plurality of fins attached to the base and two heat pipes. The fins comprise a first portion and a second portion connecting with one side of the first portion. The second portion is higher than the first portion. Each of the heat pipes comprises an evaporating portion sandwiched between the base and the first portion of the fins, and a condensing portion inserted into the second portion of the fins.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views. Other advantages and novel features will become more apparent from the following detailed description of preferred embodiment when taken in conjunction with the accompanying drawings, in which:

FIG. 1 is an exploded, isometric view of a heat dissipation device in accordance with a preferred embodiment of the present invention; and

FIG. 2 is an assembled view of FIG. 1.

### DETAILED DESCRIPTION OF THE INVENTION

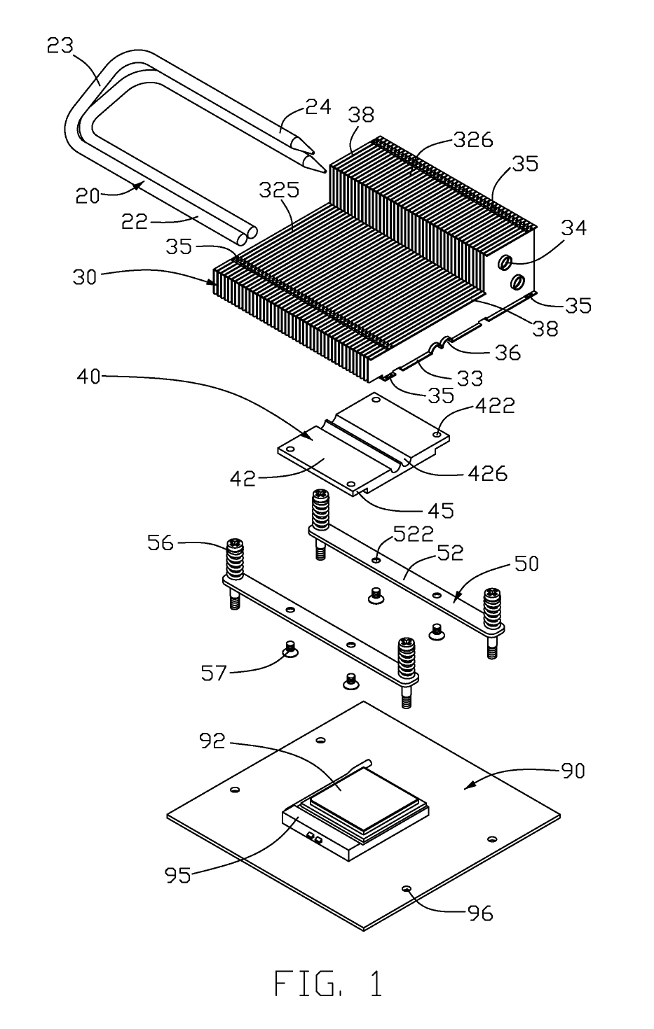

Referring to FIG. 1, a heat dissipation device of the preferred embodiment of the present invention is used for being mounted to a printed circuit board 90 to remove heat from a heat-generating electronic device mounted on the printed circuit board 90, such as a CPU 92. The CPU 92 is mounted on a socket 95 of the printed circuit board 90. The heat dissipation device comprises a base 40, a plurality of fins 30 attached to the base 40 and two heat pipes 20 connecting the base 40 and the fins 30. The heat dissipation device further comprises two locking members 50 engaging with the base 40 to secure the heat dissipation device to the printed circuit board 90.

The base 40 is a metal plate having a high heat conductivity, and has a rectangular configuration. The base 40 comprises a bottom surface (not labeled) for contacting the CPU 92 and a top surface 42 opposite to the bottom surface thereof. The base 40 defines two parallel straight grooves 426 in a top portion thereof, for receiving the heat pipes 20. The grooves 426 are located at a center of the base 40. The base 40 defines two undercuts (not labeled) in opposite sides of a bottom portion thereof to form two locking portions 45 for engaging with the locking members 50. The undercuts are parallel to the grooves 426. Each locking portion 45 defines two locking holes 422 therein at opposite ends thereof.

Each fin 30 is made of a metal sheet, and has an L-shaped configuration. The fins 30 are oriented perpendicular to the base 40 and parallel to each other. The fins 30 comprise a first portion 325 and a second portion 326 connecting with one side of the first portion 325, and the second portion 326 is higher than the first portion 325. The first portion 325 and the second portion 326 respectively form clasps 35 at top and bottom thereof. The fins 30 snappingly connect with each other via the clasps 35 formed on the top and bottom thereof. The second portion 326 of the fins 30 is far away from the base 40. The second portion 326 of the fins 30 defines a pair of separate through holes 34 transversely extending across all of the fins 30. Each fin 30 defines two adjoining slots 36 at a bottom thereof and forms a flange 33 perpendicularly extending from a bottom edge thereof. Each fin 30 forms a flange 38 perpendicularly extending from a top edge thereof. The slots 36 cooperate with the grooves 426 to define channels (not labeled) for receiving the heat pipes 20, when the fins 30 are stacked together and mounted onto the base 40. The flanges 33, 38 separate the fins 30 by uniform intervals.

The heat pipes 20 are U-shaped. Each heat pipe 20 comprises a horizontal evaporating portion 22, a condensing portion 24 parallel to the evaporating portion 22 and an adiabatic portion 23, connecting the evaporating portion 22 and the condensing portion 24.

Each locking member 50 comprises a locking beam 52 engaging with the corresponding locking portion 45 of the base 40. A pair of mounting holes 522 are defined in the locking beam 52. Screws 57 are extended through the mounting holes 522 and threadedly engaged in the locking holes 422 of the base 40, thereby securing the locking members 50 to the base 40. The heat sink 30 is fastened onto the CPU 92 by extending a pair of fasteners 56 through each locking beam 52 to engage with a retainer (not shown) below the printed circuit board 90. The fasteners 56 are located at opposite ends of each locking beam 52 and extended through four mounting holes 96 on the printed circuit board 90.

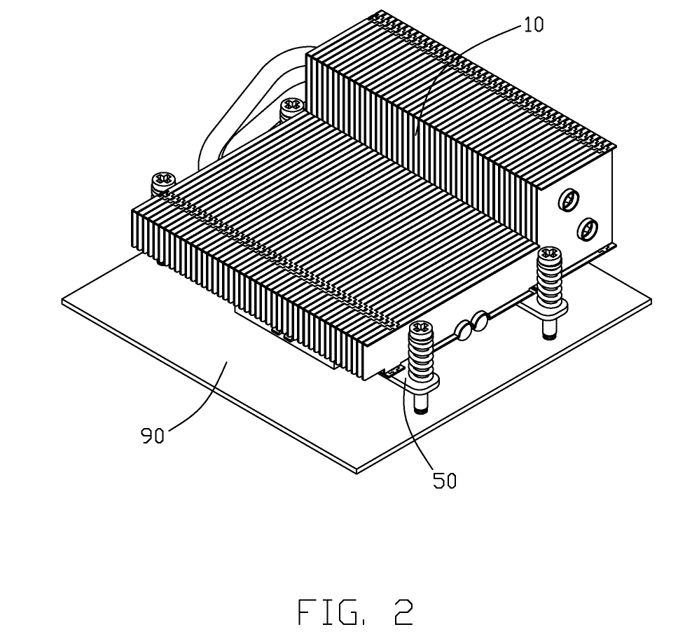

Referring also to FIG. 2, in assembly of the heat dissipation device, the evaporating portions 22 are soldered in the channels (not labeled) defined by the grooves 426 of the base 40 and the slots 36 of the fins 30. The bottom of the fins 30 are soldered to the top surface of the base 40 and thermally contact the base 40 and the evaporating portions 22 of the heat pipes 20. The condensing portions 24 are soldered in the through holes 34 of the second portion 326 of the fins 30 and thermally contact the second portion 326 of the fins 30.

The evaporating portions 22 are located at the centre of the base 40. The condensing portions 24 are mounted in the second portion 326 of the fins 30 remote from the CPU 92. As a result, the evaporating portions 22 of the heat pipes 20 are aligned with the CPU 92. The base 40 absorbs heat generated by the CPU 92. Then a part of the heat accumulated on the base 40 is absorbed by the evaporating portions 22 of the heat pipes 20 and transferred to the second portion 326 of the fins 30 via the adiabatic portions 23 and the condensing portions 24 of the heat pipes 20. Another part of the heat accumulated on the base 40 is directly transferred to the first portion 325 of the fins 30. Thus the heat generated by the CPU 92 can be quickly and evenly transferred to the whole of each of the fins 30, and heat dissipation efficiency of the heat dissipation device is improved accordingly.

An airflow generated by a fan (not shown) is divided into upper and lower airflow after the airflow passes through the fins 30 from a rear side to a front side of the fins 30 as viewed from FIGS. 1 and 2. The upper airflow (i.e., a branch of the airflow flowing through an upper part of the second portion 326 and above the first portion 325 of the fins 30) can be used to blow other heat-generating electronic components (not shown) mounted on printed circuit board 90 and in front of the first portion 325 of the fins 30, wherein the other electronic components have a height higher than that of the first portion 325 of the fins 30. The lower airflow (i.e., a branch of the airflow flowing through the first portion 325 of the fins 30) can take heat generated by the CPU 92 away therefrom. Thus, the airflow generated the fan can take way heat not only generated by the CPU 92 but also generated by the other electronic components.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a base for contacting a heat-generating device;
a plurality of L-shaped fins attached to the base, the fins comprising a first portion and a second portion connecting with the first portion, the second portion being higher than the first portion, the second portion being positioned remote from the base; and
a pair of heat pipes, each of the heat pipes comprising an evaporating portion sandwiched between the base and the first portion of the fins, and a condensing portion received in the second portion of the fins.

2. The heat dissipation device as described in claim 1, wherein the fins are oriented perpendicular to the base.

3. The heat dissipation device as described in claim 1, wherein the fins are parallel to each other.

4. The heat dissipation device as described in claim 3, wherein the fins are snappingly connected to each other via a fastening portion.

5. The heat dissipation device as described in claim 1, wherein the base defines two parallel straight grooves in a top portion thereof to receive the evaporating portions of the heat pipes.

6. The heat dissipation device as described in claim 5, wherein the fins define slots to receive the evaporating portions of the heat pipes.

7. The heat dissipation device as described in claim 1, wherein the second portion of the fins defines two holes to receive the condensing portions of the heat pipes.

8. The heat dissipation device as described in claim 1, wherein the fins are soldered to the top surface of the base.

9. A heat dissipation device comprising:
a base having a top surface;
a plurality of parallel fins comprising a first portion attached to the top surface of the base and a second portion located beyond the base, the first portion snappingly connecting with each other via first clasps formed at opposite top and bottom portions of the first portion, the second portion snappingly connecting with each other via second clasps formed at opposite top and bottom portions of the second portion; and
at least a heat pipe comprising an evaporating portion sandwiched between the base and the first portion of the fins and a condensing portion received in the second portion of the fins.

10. The heat dissipation device as described in claim 9, wherein each of the fins has an L-shaped configuration.

11. The heat dissipation device as described in claim 10, wherein the fins are oriented perpendicular to the base.

12. The heat dissipation device as described in claim 11, wherein two locking members engage with the base adapted to secure the heat dissipation device to a printed circuit board.

13. The heat dissipation device as described in claim 9, wherein a pair of locking members are mounted beneath the base adapted to mount the heat dissipation device on a printed circuit board.

14. The heat dissipation device as described in claim 13, wherein the locking members are elongated and parallel to each other.

15. The heat dissipation device as described in claim 13, wherein a pair of fasteners extend through each of the locking members at opposite ends of the each of the locking members.

16. A heat dissipation device comprising:
a base for contacting with a heat-generating electronic component;
a plurality of fins having a first portion mounted on the base and a second portion beside the base, the second portion having a height larger than that of the first portion; and
a heat pipe having an evaporating portion thermally connecting with the base and a condensing portion thermally connecting the second portion of the fins;
wherein an airflow through the fins is divided into an upper branch and a lower branch, the upper branch flowing through an upper part of the second portion of the fins and above the first portion of the fins, the lower branch flowing through the first portion of the fins.

17. The heat dissipation device as described in claim 16, wherein the evaporating portion of the heat pipe is sandwiched between the first portion of the fins and the base, and the condensing portion of the heat pipe is inserted in the second portion of the fins.
